(19) United States
(12) Patent Application Publication
(10) Pub. No.: US 2024/0322001 A1
(43) Pub. Date: Sep. 26, 2024

(54) METHOD OF MANUFACTURING A SEMICONDUCTOR DEVICE HAVING A TRENCH CAPACITOR AND A LOGIC DEVICE

(71) Applicant: SK keyfoundry Inc., Cheongju-si (KR)

(72) Inventor: Jong Hyuk OH, Cheongju-si (KR)

(73) Assignee: SK keyfoundry Inc., Cheongju-si (KR)

(21) Appl. No.: 18/476,888

(22) Filed: Sep. 28, 2023

(30) Foreign Application Priority Data
Mar. 23, 2023 (KR) 10-2023-0038099

(51) Int. Cl. H01L 29/66; H01L 29/94

(52) U.S. Cl. CPC H01L 29/66181; H01L 28/91; H01L 29/945

(57) ABSTRACT

A method of manufacturing a semiconductor device includes: forming a deep trench in a substrate; performing an ion implantation process to form a lower electrode along with the deep trench; forming a dielectric layer on the lower electrode; filling a first conductive layer into the deep trench; performing a planarization process on the first conductive layer to form an upper electrode in the deep trench such that a trench capacitor is formed in the deep trench; forming a shallow trench adjacent to the deep trench; forming a logic gate insulating layer adjacent to the shallow trench; forming a logic gate electrode on the logic gate insulating layer; and forming a source region and a drain region adjacent to the logic gate electrode. The logic gate electrode is made of a same material as the upper electrode.

### CROSS-REFERENCE TO RELATED APPLICATION

This application is based on and claims the benefit under 35 U.S.C. § 119(a) of Korean Patent Application No. 10-2023-0038099 filed on Mar. 23, 2023 in the Korean Intellectual Property Office, the entire disclosure of which is incorporated herein by reference for all purposes.

### BACKGROUND

### 1. Field

The following description relates to a method of manufacturing a semiconductor device including trench capacitors and logic devices.

### 2. Description of Related Art

A high-density trench capacitor is discretely fabricated with a first chip. An integrated circuit (IC) chip (second chip) including signal processing devices is manufactured, and the second chip may be combined with the first chip by a multi-chip packaging process, resulting in a multi-chip semiconductor device. A total manufacturing cost of the multi-chip semiconductor device may increase because each of the multi-chips is manufactured separately. Therefore, it is necessary to use an integrated circuit (IC) chip including the signal processing devices and the high-density trench capacitor formed on a monolithic die (or single die).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method of manufacturing a semiconductor device includes: forming a deep trench in a substrate; performing an ion implantation to form a lower electrode along with the deep trench; forming a dielectric layer on the lower electrode; filling a first conductive layer into the deep trench; performing a planarization process on the first conductive layer to form an upper electrode in the deep trench such that a trench capacitor is formed in the deep trench; forming a shallow trench adjacent to the deep trench; forming a logic gate insulating layer adjacent to the shallow trench; forming a logic gate electrode on the logic gate insulating layer; and forming a source region and a drain region adjacent to the logic gate electrode. The logic gate electrode is made of a same material as the upper electrode.

The forming of the deep trench in the substrate may include forming a deep trench hard mask pattern on the substrate; and performing an etching process on the substrate to form the deep trench with the deep trench hard mask pattern.

The forming of the dielectric layer on the lower electrode may include forming a first dielectric layer in the deep trench; and forming a second dielectric layer on the first dielectric layer, and the first dielectric layer comprises a first material that is different from a second material of the second dielectric layer.

The method may further include forming thermal oxide layers on the upper electrode and the logic gate electrode; and forming spacers on sidewalls of the upper electrode and the logic gate electrode.

The method may further include performing a high temperature annealing process on the planarized first conductive layer or the upper electrode.

The performing of the planarization process on the first conductive layer to form the upper electrode in the deep trench may include performing a first chemical mechanical planarization (CMP) process on the first conductive layer to form a planarized first conductive layer; and a second CMP process to remove the dielectric layer exposed by the first CMP.

The method may further include performing a gap-fill process on the shallow trench with a thick insulating layer; and performing a third CMP process on the thick insulating layer.

In another general aspect, a method of manufacturing a semiconductor device includes: providing a first region and a second region in a semiconductor substrate; forming a deep trench hard mask pattern in the second region; forming a deep trench in the second region with the deep trench hard mask pattern; forming a lower electrode along with the deep trench; forming a dielectric layer on the lower electrode; performing a gap-filling process in the deep trench with a first conductive layer; performing a first planarization process on the first conductive layer to form an upper electrode in the deep trench; forming a shallow trench hard mask pattern in the first region; forming a shallow trench in the first region with the shallow trench hard mask pattern; filling the shallow trench with a thick insulating layer; performing a second planarization process on the thick insulating layer to form a planarized thick insulating layer in the shallow trench; forming a logic gate insulating layer adjacent to the shallow trench; forming a second conductive layer on the logic gate insulating layer; performing a patterning process on the second conductive layer to form a logic gate electrode in the first region; and forming a source region and a drain region around the logic gate electrode. The first conductive layer is a same material as the second conductive layer.

The forming of the lower electrode may include performing an ion implantation process along with the deep trench.

The method may further include forming a thermal oxide layer on each surface of the logic gate electrode and the upper electrode.

The performing of the first planarization process on the first conductive layer to form the upper electrode in the deep trench may include performing a first chemical mechanical planarization (CMP) process on the first conductive layer to form a planarized first conductive layer; and performing a second CMP process to remove the dielectric layer exposed by the first CMP.

The method may further include performing a high temperature annealing process on the planarized first conductive layer or the upper electrode.

In another general aspect, a method of manufacturing a semiconductor device includes: providing a first region and a second region in a substrate; forming a deep trench in the second region; forming a lower electrode along with the deep trench; forming a dielectric layer on the lower electrode; filling a first conductive layer into the deep trench; performing a planarization process on the first conductive layer to form an upper electrode in the deep trench such that a trench capacitor is formed in the deep trench; forming a shallow trench adjacent to the deep trench; filling the shallow trench with a thick insulating layer to form a shallow trench isolation; forming a first gate insulating layer on the substrate in the first region, and forming a second gate insulating layer on the upper electrode in the second region; forming a second conductive layer on the first and second gate insulating layers; performing a patterning process on the second conductive layer to form a logic gate electrode in the first region; and forming source and drain regions adjacent to the logic gate electrode.

The dielectric layer may include a first insulating layer, a second insulating layer, and a third insulating layer. The first and third insulating layers are formed of a same material, and the second insulating layer is formed of a material different from that of the first and third insulating layers.

The first and third insulating layers may include Al₂O₂ or SiO₂, and the second insulating layer may include HfO₂, SiN or SiON.

Other features and aspects will be apparent from the following detailed description, the drawings, and the claims.

### BRIEF DESCRIPTION OF THE DRAWINGS

FIG. 1 illustrates a sectional view of a semiconductor device according to one or more examples of the present disclosure.

FIG. 2 illustrates an overall process flow of a semiconductor device according to one or more examples of the present disclosure.

FIGS. 3A to 21 illustrate a method of manufacturing a semiconductor device according to one or more examples of the present disclosure.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

Throughout the specification, when an element, such as a layer, region, or substrate, is described as being “on,” “connected to,” or “coupled to” another element, it may be “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As implemented herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section.

The terms “comprises,” “comprises,” and “has” specify the presence of stated features, numbers, operations, members, elements, and/or combinations thereof, but do not preclude the presence or addition of one or more other features, numbers, operations, members, elements, and/or combinations thereof.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terms indicating a part such as “part” or portion” used herein to mean that the component may represent a device that may comprise a specific function, a software that may comprise a specific function, or a combination of device and software that may comprise a specific function, but it is not necessarily limited to the function expressed. This is only provided to help a more general understanding of one or more examples herein, Various modifications and variations are possible from these descriptions by those of ordinary skill in the art to which the one or more examples pertains.

In addition, it should be noted that all electrical signals used herein are examples, and when an inverter or the like is additionally provided in the circuit in accordance with one or more embodiments, the signs of all electrical signals to be described below may be reversed. Accordingly, the scope of the embodiments is not limited to the direction of the signal.

The features of the examples described herein may be combined in various ways as will be apparent after an understanding of the disclosure of this application. Further, although the examples described herein have a variety of configurations, other configurations are possible as will be apparent after an understanding of the disclosure of this application.

A detailed description is given below, with attached drawings. The features of the examples described herein may be combined in various ways as will be apparent after an understanding of the disclosure of this application. Further, although the examples described herein have a variety of configurations, other configurations are possible as will be apparent after an understanding of the disclosure of this application.

The present disclosure is provided to suggest a manufacturing method for a semiconductor device capable of ensuring the performance of a logic device having a trench capacitor.

The present disclosure is also provided to suggest a way for reducing the manufacturing cost of a semiconductor device by fabricating two chips in a one-chip form.

The technical problems of the present disclosure are not limited to the technical problems mentioned above, and other technical problems not mentioned may be clearly understood by those skilled in the art from the following description.

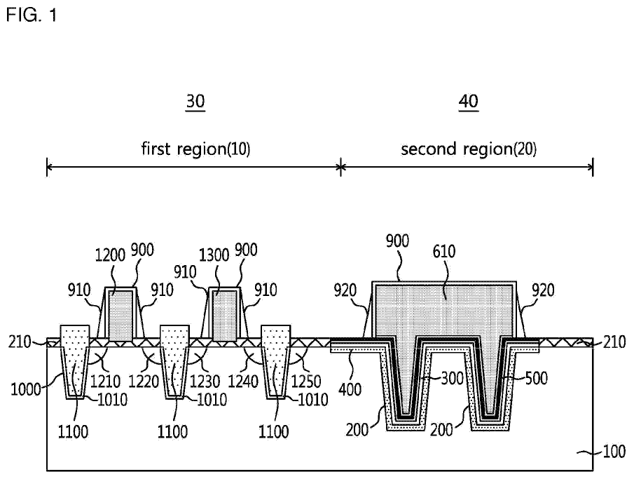

FIG. 1 illustrates a sectional view of a semiconductor device according to one or more examples of the present disclosure.

Referring to FIG. 1, in a semiconductor device, a semiconductor substrate 100 may be divided into a first region 10 and a second region 20. The first region 10 may comprise a logic circuit, an analog circuit, a digital circuit, or a mixed signal circuit. Thus, the first region 10 may perform analog, logic or digital signal processing. The first region 10 may include logic devices 30. The second region 20 may comprise a trench capacitor 40 which may charge or discharge carriers such as holes or electrons for the analog, logic or digital signal processing.

In the first region 10, first and second gate electrodes 1200 and 1300 are formed over the substrate 100. The first gate electrode 1200 may be an NMOS gate. The second gate electrode 1300 may be a PMOS gate. The NMOS and PMOS gates 1200 and 1300 may be referred to as logic gates. N+ source/drain regions 1210 and 1220 may be formed adjacent to the NMOS gate 1200. P+ source/drain regions 1230 and 1240 may be formed adjacent to the PMOS gate 1300. Spacers 910 may be formed on the sidewalls of the NMOS and PMOS gates 1200 and 1300.

Further, shallow trenches 1000 are formed between the NMOS and PMOS gates 1200 and 1300. A pick-up region 1250 may be formed on an active region adjacent to one of the shallow trench 1000.

In the second region 20, the trench capacitor 40 may be formed adjacent to the logic devices 30. The trench capacitor 40 may comprise a lower electrode 400, a dielectric layer 500, and an upper electrode 610. A deep trench 200 may be formed for the trench capacitor 40. The doped region 400 as a lower electrode of the trench capacitor 40 may be formed along with sidewalls of the deep trench 200. The doped region 400 may be formed by an in-situ doping process with an N-type POCI3 gas. In addition, the dielectric layer 500 may be formed on the doped region 400. Further, the upper electrode 610 may be formed on the dielectric layer 500.

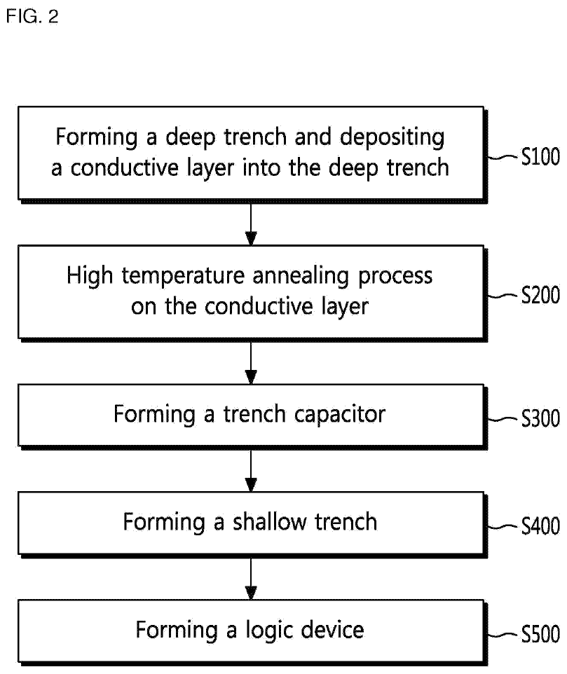

FIG. 2 illustrates an overall process flow chart of a semiconductor device according to one or more examples of the present disclosure.

The present disclosure proposes a method of manufacturing an embedded semiconductor device by integrating logic devices 30 and a trench capacitor 40 into a single chip.

Specifically, referring to FIG. 2, a first step S100 is for forming a deep trench in the substrate and depositing a conductive layer into the deep trench. A second step S200 is for performing a high temperature annealing process on the conductive layer. A third step S300 is for forming a trench capacitor 40. A fourth step S400 is for forming a shallow trench to separate the logic devices 30. The fifth step S500 is for forming the logic devices 30.

The high temperature annealing process in the second step S200 is performed during the fabrication of the trench capacitor 40. The high temperature annealing process at the second step S200 may affect the diffusion of dopants implanted in the substrate. The logic device 30 may be more sensitive to dopant diffusion than the trench capacitor 40. Therefore, it is recommended that the high temperature annealing process be performed prior to forming the logic device 30. If the logic device 30 is formed followed by the high temperature annealing process for the trench capacitor 40, the electrical characteristics of the logic device 30 may be degraded by the high temperature annealing process.

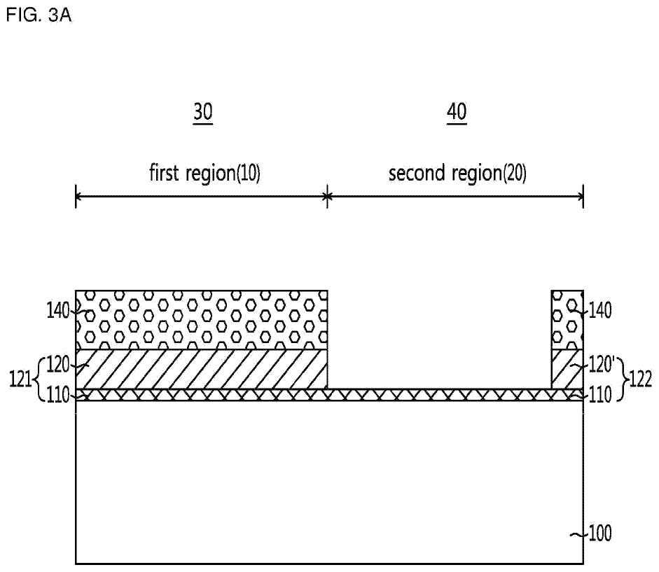

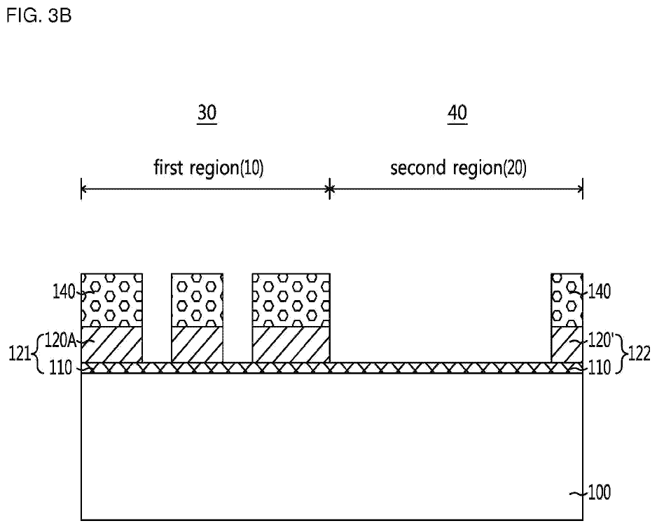

The method of manufacturing a semiconductor device according to one or more examples of the present disclosure will be described in FIGS. 3 to 21.

FIGS. 3A to 10 illustrate forming a trench capacitor.

FIG. 3A illustrates a patterning process of insulating layers on a semiconductor substrate.

Referring to FIG. 3A, a pad oxide layer 110 is deposited on a semiconductor substrate by a thermal oxidation process, and then an insulating nitride layer (not shown) is formed on the pad oxide layer 110 by a chemical vapor deposition (CVD) process. A first photoresist pattern 140 is formed on the insulating nitride layer. A patterning process may be performed on the insulating nitride layer to form a pad nitride pattern 120 with the first photoresist pattern 140 in the first region 10. Thus, the pad nitride pattern 120 may include a silicon nitride layer. The pad oxide layer 110 may be partially etched during the patterning process and still remain on the first region 10 and the second region 20.

The patterning process may also form a dummy pattern 122 in the second region 20, wherein the dummy patterns 122 may comprise the pad oxide layer 110 and another pad nitride pattern 120′. The dummy patterns 122 may be helpful in preventing a dishing phenomenon in a chemical mechanical planarization (CMP) process. The dummy patterns 122 may increase pattern uniformity in the semiconductor device.

After forming the pad nitride pattern 120 and the dummy pattern 122, the first photoresist pattern 140 is removed.

FIG. 3B illustrates an optional patterning process of insulating layers on a semiconductor substrate.

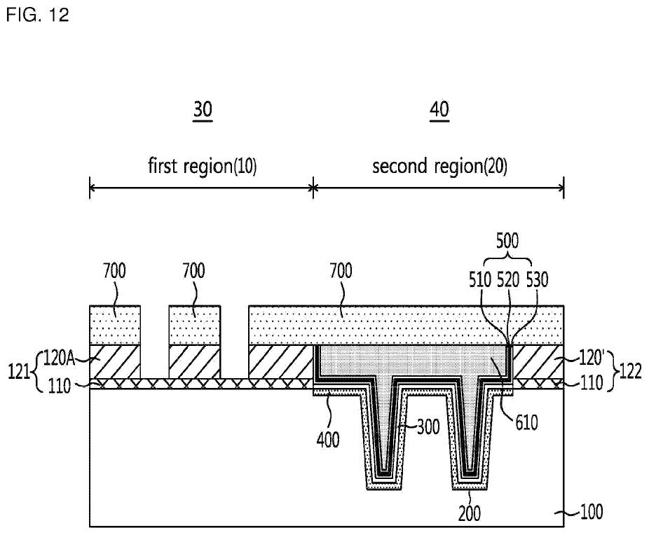

Referring to FIG. 3B, a patterning process is performed on an insulating nitride layer (not shown) with a first photoresist pattern 140 to form a shallow trench hard mask pattern 120A. If the shallow trench hard mask pattern 120A is not required in the first step S100, the patterning process for the shallow trench hard mask pattern 120A can be skipped. Instead, the patterning process for the shallow trench hard mask pattern 120A may be performed at the fourth step S400, i.e., forming a shallow trench (see FIG. 12), with a new photomask pattern 700.

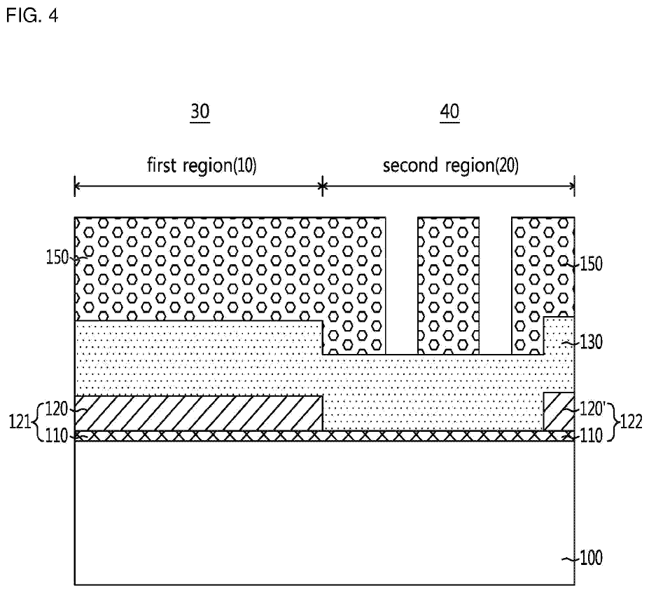

FIG. 4 illustrates the formation of a second hard mask layer.

Referring to FIG. 4, to form a deep trench, a thick insulating layer 130 may be deposited on the pad nitride pattern 120 and the pad oxide layer 110 to form a deep trench hard mask pattern. The thick insulating layer 130 may be selected from one or a combination of SiO2, SiON, SiN, HDP, TEOS, USG, and BPSG. The thick insulating layer 130 may have a thickness greater than a thickness of the pad nitride pattern 120.

A second photoresist pattern 150 may subsequently be formed on the thick insulating layer 130 for a subsequent pattering process.

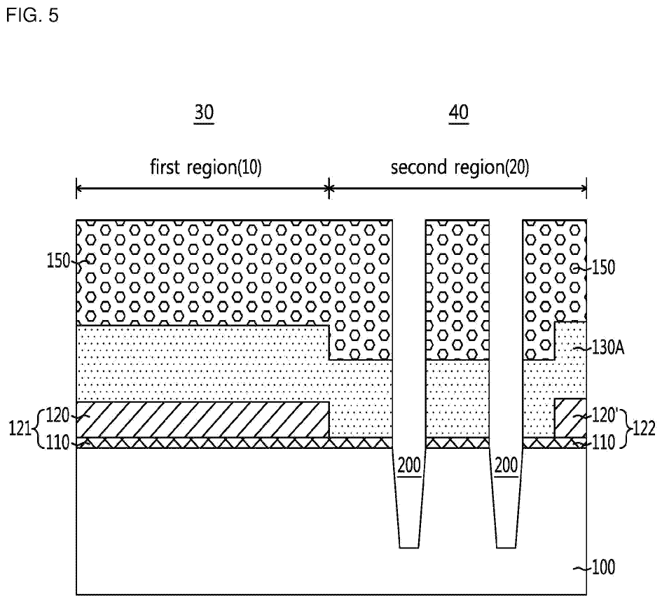

FIG. 5 illustrates the formation of a deep trench in the second region.

Referring to FIG. 5, a reactive ion etching (RIE) process may be performed on the thick insulating layer 130 to form a deep trench hard mask pattern 130A with the second photoresist pattern 150. Here, the reactive ion etching (RIE) process belongs to a dry etching process. The RIE process is further performed to form a deep trench 200 in the second region 20 with the second photoresist pattern 150 and the deep trench hard mask pattern 130A.

The deep trench 200 may be formed to a predetermined depth in the semiconductor substrate 100. For example, the deep trench 200 may have a depth of 10 ˜100 μm. As the depth of the deep trench increases, the capacitance of the trench capacitor 40 may increase. A suitable etching process condition may be applied to form the deep trench 200 having a predetermined depth in the semiconductor substrate 100.

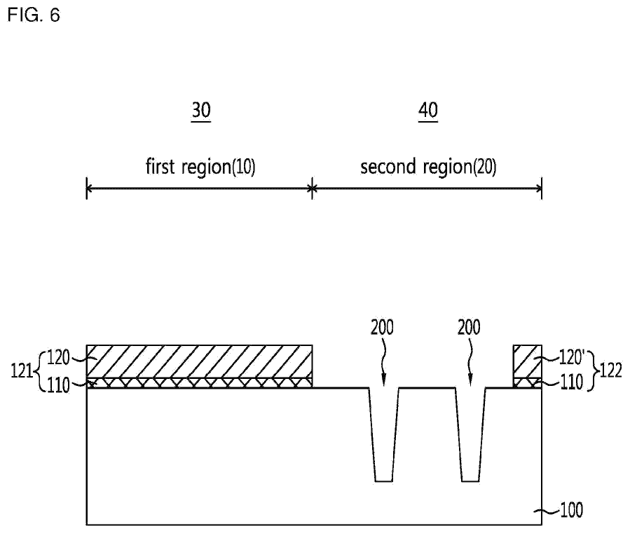

Referring to FIG. 6, after forming the deep trench 200, the second photoresist pattern 150 and the deep trench hard mask pattern 130A may be removed. In addition, the pad oxide layer 110 in the second region may also be removed. Accordingly, only the pad nitride pattern 120 may remain in the first region 10. The dummy pattern 122 may still remain in the second region 20.

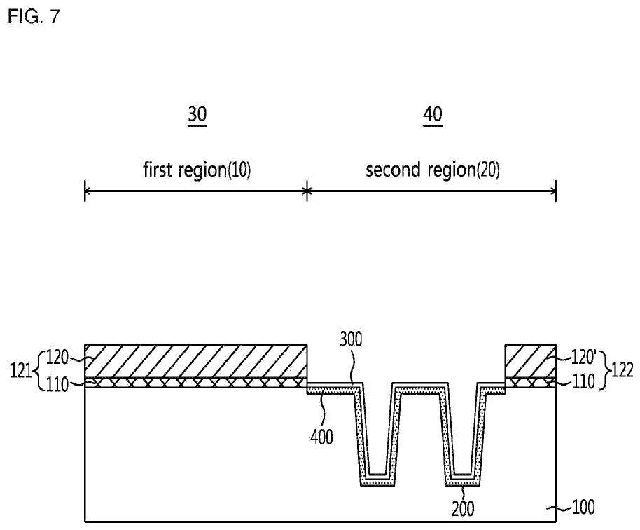

FIG. 7 illustrates the formation of a lower electrode along with the deep trench.

Referring to FIG. 7, a thermal oxide layer 300 may be formed on the sidewalls of the deep trench 200. The thermal oxide layer 300 may be formed by oxidizing the surface of the deep trench with oxygen gas at a high temperature. The thermal oxide layer 300 serves to relieve stress generated during formation of the deep trench 200 and to mitigate etch damage.

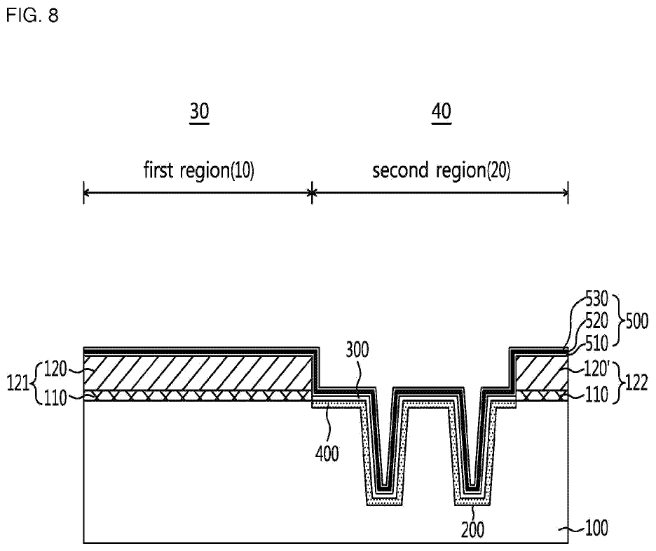

A highly doped region 400 is formed by an in-situ doping process to form the lower electrode. N-type dopants from POCI3 gases are doped along with the deep trench. The highly doped region 400 may be formed under the thermal oxide layer 300. The highly doped region 400 may be formed along with the deep trench 200, as well as on an upper surface of the semiconductor substrate 100. In the case where the semiconductor substrate 100 is P-type, the highly doped region 400 may be formed as N-type. In the case where the semiconductor substrate 100 is N-type, the highly doped region 400 may be formed as P-type. The highly doped region 400 may be used as a lower electrode of the trench capacitor 40 according to one or more examples of the present disclosure. FIG. 8 is a step of forming a dielectric layer on the lower electrode.

Referring to FIG. 8, a dielectric layer 500 is deposited on the thermal oxide layer 300 and the highly doped region 400. In this example, the dielectric layer 500 may comprise a first insulating layer 510 and a second insulating layer 520. Alternatively, the dielectric layer 500 may comprise a first insulating layer 510, a second insulating layer 520, and a third insulating layer 530.

The first insulating layer 510 and the third insulating layer 530 may be formed of the same material, and the second insulating layer 520 may be formed of a completely different material than the first insulating layer 510 and the third insulating layer 530. The first insulating layer 510 or the third insulating layer 530 may be selected from Al2O3 or SiO2. The second insulating layer 520 may be selected from HfO2, SiN, or SiON.

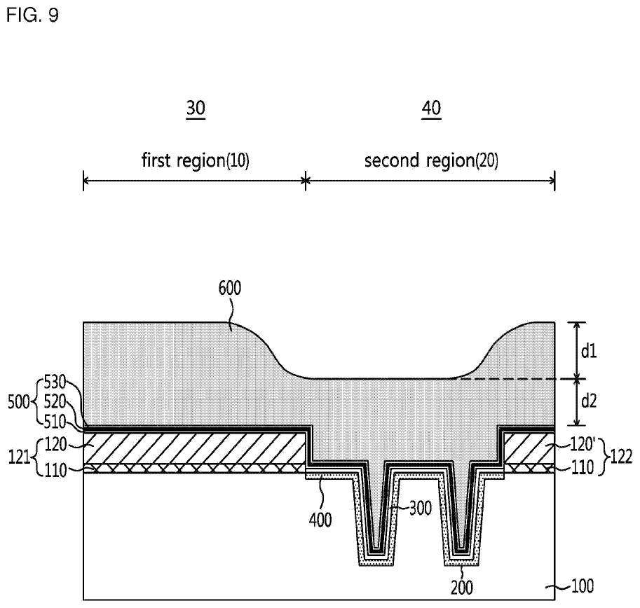

FIG. 9 illustrates the deposition of a first conductive layer on the dielectric layer.

Referring to FIG. 9, a first conductive layer 600 for forming an upper electrode may be deposited with a polysilicon (Poly-Si) or a metal layer such as TIN, TaN, Al or Cu.

The first conductive layer 600 may be deposited uniformly throughout the dielectric layer 500, including the interior of the deep trench 200 by CVD process. In examples, the first conductive layer 600 may be deposited with a thickness ranging from 50 to 1000 nm.

After the first conductive layer 600 is deposited, a high temperature annealing process is performed. When the first conductive layer 600 may use a Poly-Si layer that imparts a tensile stress or a compressive stress to the wafer, the wafer may have a warping or a bowing phenomenon after the first conductive layer 600 is deposited. The high temperature annealing process is performed to ameliorate any warping or bowing phenomena that may occur on the semiconductor substrate 100 after the deposition of the first conductive layer 600. In examples, the high temperature annealing process may be performed in a nitrogen atmosphere and a low oxygen (O2) concentration at a high temperature ranging from 950 to 1200° C.

The high temperature annealing process may affect the diffusion of dopants implanted in the substrate. If the logic device 30 is fabricated and then subjected to the high temperature annealing process, electrical characteristics such as threshold voltage (Vt) may be degraded because the high temperature annealing process may cause a negative effect on Vt.

The logic device 30 may be fabricated after the high temperature annealing process. Thus, the logic device 30 formed in the first region 10 may not be affected by the high temperature annealing process. Accordingly, deterioration of the characteristics of the logic device 30 may be reduced.

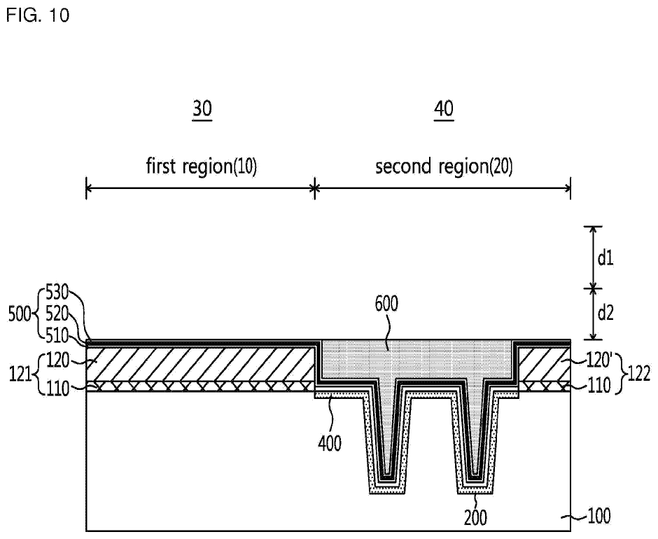

FIG. 10 illustrates a chemical mechanical planarization (CMP) process.

Referring to FIG. 10, a first CMP process may be performed on the first conductive layer 600 until the dielectric layer 500 is exposed. During the first CMP process, the dielectric layer 500 may serve as an etch stop layer. The thickness of the Poly-Si 600 to be etched may be d1+d2. After the first CMP process, the dielectric layer 500 may be exposed. The first conductive layer (Poly-Si) 600 may become a planarized first conductive layer (Poly-Si) 600 by the first CMP process. The planarized first conductive layer (Poly-Si) 600 may play a role of an upper electrode in the trench capacitor 40.

The high temperature annealing process may be performed after the planarization process on the first conductive layer 600, rather than immediately after depositing a first conductive layer 600 on the dielectric layer. The high temperature annealing process may be performed on the planarized first conductive layer 600 or on an upper electrode 610.

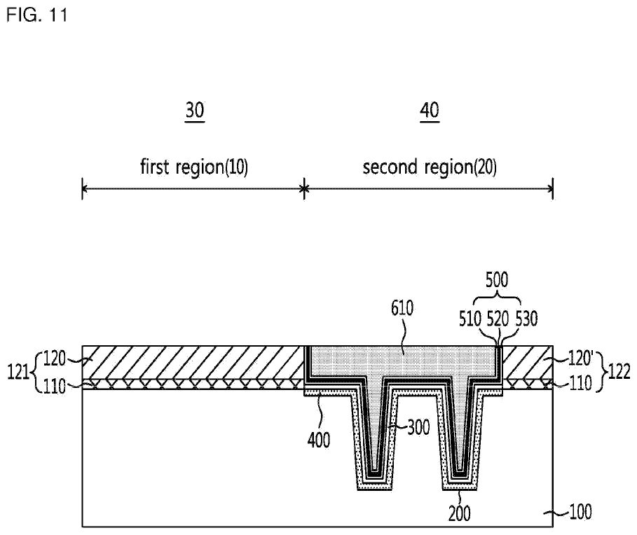

FIG. 11 illustrates removing the exposed dielectric layer and forming the upper electrode in the deep trench.

Referring to FIG. 11, a second CMP process may further be performed to remove the exposed dielectric layer 500 outside the deep trench 200 after the first CMP process. The second CMP process conditions may be different from the first CMP process due to different materials between the dielectric layer 500 and the first conductive layer 600. As another example, the second CMP process conditions may be the same as the first CMP process despite different materials in order to reduce a semiconductor manufacturing cost.

During the second CMP process, a portion of the planarized first conductive layer 600 may also be lightly removed. In this context, the planarized first conductive layer 600 may be referred to as an upper electrode 610 in the trench capacitor 40. The high temperature annealing process may be performed on the upper electrode 610 rather than immediately after the deposition of the first conductive layer 600.

After the first CMP or the second CMP, an upper surface of the upper electrode 610 and an upper surface of the pad nitride pattern 120 may be coplanar with each other. In other words, the upper electrode 610 may have the same plane as the pad nitride pattern 120.

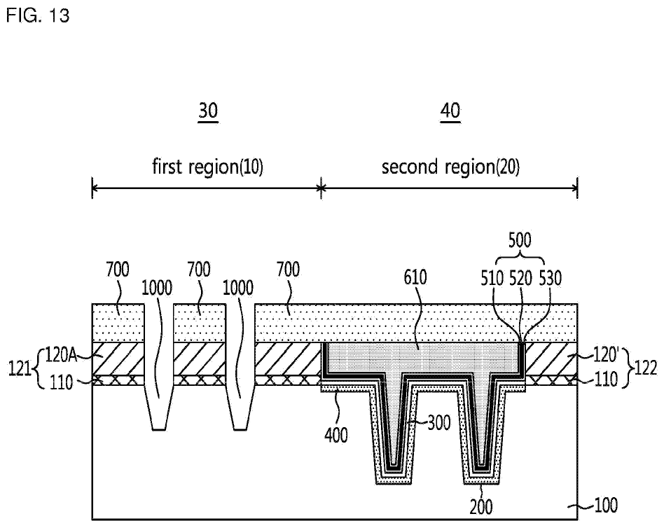

FIGS. 12 and 13 illustrate the formation of a logic device.

Referring to FIG. 12, a patterning process is performed on the pad nitride pattern 120 with a third photoresist pattern 700 as a mask pattern. A pad nitride pattern 120 is transformed into a shallow trench hard mask pattern 120A.

Referring to FIG. 13, a reactive ion etching (RIE) process is performed to form a shallow trench 100 in the first region 10 with the third photoresist pattern 700 and the shallow trench hard mask pattern 120A. Shallow trench 1000 having a predetermined depth may be formed in the semiconductor substrate 100. Each of the shallow trenches 1000 may have a depth that is less than a depth of the deep trench 200.

The third photoresist pattern 700 is removed by an ashing process after the shallow trench 1000 is formed. In addition, a post-cleaning process may be further performed to remove polymer residues.

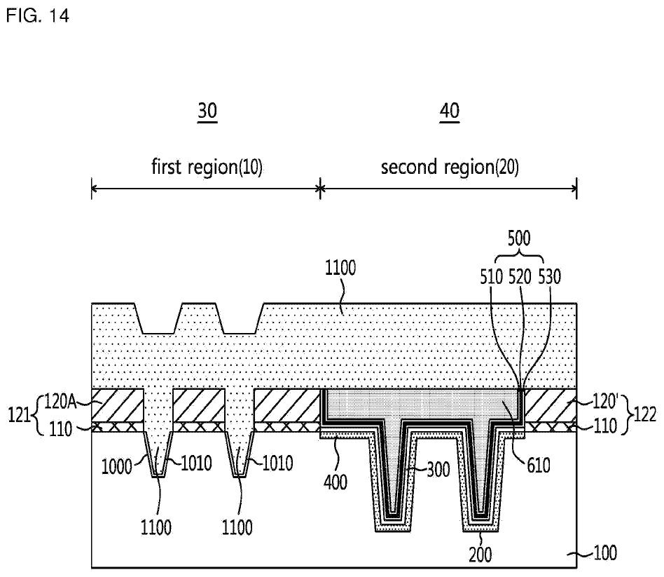

FIGS. 14 through 16 illustrate the process of gap-filling in the shallow trench isolations.

Referring to FIG. 14, a thin thermal oxide layer 1010 may be formed on the sidewalls of the shallow trench 1000 by a thermal oxidation process. The thermal oxidation process cures etch damage caused during the RIE etching process.

FIG. 14 also illustrates a gap-filling process with a thick insulating layer 1100 in the shallow trench 1000. The thick insulating layer 1100 may be formed with a predetermined thickness with respect to the entire area of the semiconductor substrate 100. The thick insulating layer 1100 may comprise a high density plasma (HDP) oxide material.

In addition, the thick insulating layer 1100 is also formed on the upper electrode 610. The thick insulating layer 1100 may be formed in contact with the upper electrode 610.

After the gap-filling process is performed, an annealing process may be performed with a rapid thermal annealing (RTP) process to densify the thick insulating layer 1100. When the annealing process is completed, the shallow trench 1000 may be filled with the HDP oxide layer 1100.

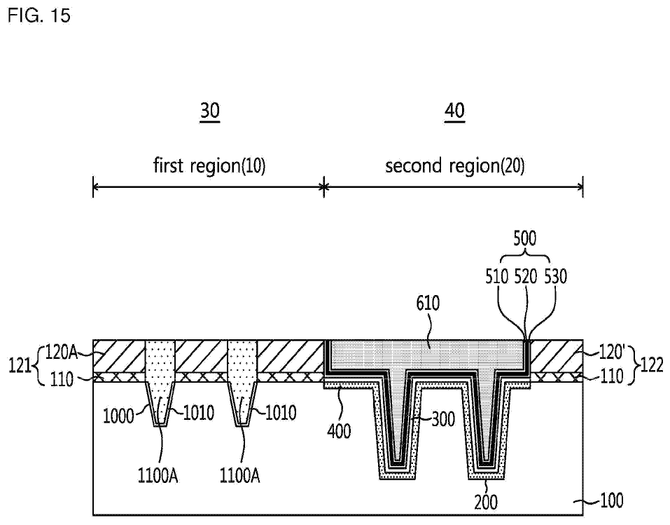

Referring to FIG. 15, a third CMP process is performed to planarize the thick insulating layer 1100 until the shallow trench hard mask pattern 120A is exposed. After the third CMP process, the thick insulating layer 1100 becomes a planarized thick insulating layer 1100A. The shallow trench 1000 can be filled with the planarized thick insulating layer or a planarized HDP oxide layer 1100A. Thereafter, the shallow trench 1000 may be referred to as a shallow trench isolation region 1000 filled with the planarized thick insulating layer 1100A. After the third CMP process, a top surface of the upper electrode 610 may be exposed again.

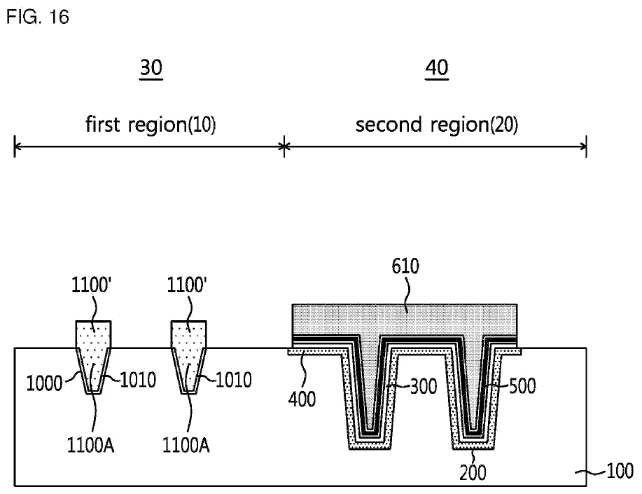

Referring to FIG. 16, both the shallow trench hard mask pattern 120A and the dummy pattern 121 are removed by a first wet etching process. A dilute HF (DHF) solution and a phosphoric acid solution may be used for the wet etching process. In lieu of a wet etching process, it can be removed by a dry etching process.

The pad oxide layer 110 may be easily removed by a second wet etching process with a DHF solution. Once the pad oxide layer 110 is removed, the surface of the semiconductor substrate 100 may be exposed.

The first/second insulating layers 510 and 520 may also be exposed during the first and second wet etching processes. The exposed first/second insulating layers 510 and 520 are readily removed by the chemical solutions used in the first and second wet etching processes. After the first and second wet etching processes, both the side and top surfaces of the upper electrode 610 may be exposed.

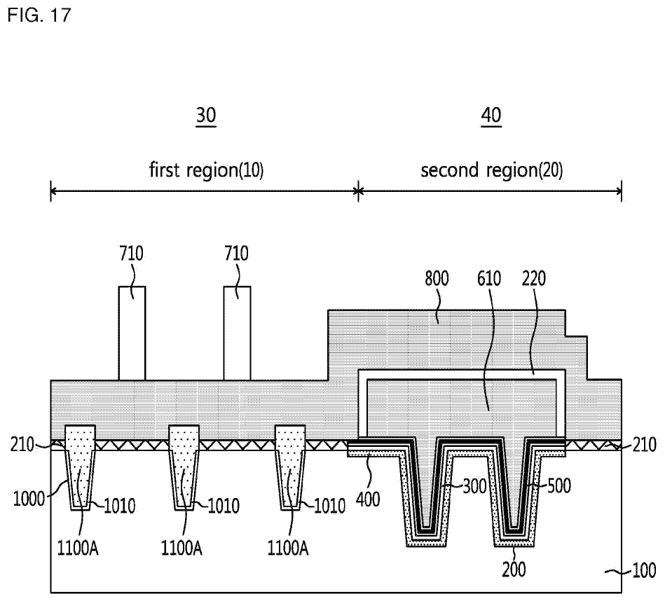

FIG. 17 illustrates forming a gate insulating layer on the semiconductor substrate and depositing a second conductive layer on the gate insulating layer.

Referring to FIG. 17, a thermal oxidation process may be performed to form a first gate insulating layer 210 and a second gate insulating layer 220 in the first region and the second region, respectively. The first gate insulating layer 210 may be formed on the surface of the semiconductor substrate 100 in the first region. The second gate insulating layer 220 may be formed on the surface of the upper electrode 610 in the second region. If necessary, the first gate insulating layer 210 and the second gate insulating layer 220 may be formed by the CVD method.

Next, a second conductive layer 800 may be formed on the first and second gate insulating layers 210 and 220. The second conductive layer 800 may be made of materials such as Poly-Si, Cu, Al, W, TIN, etc. The second conductive layer 800 is the same material as the first conductive layer 600.

A hard mask layer (not shown) may be formed on the second conductive layer 800. Thereafter, a fourth photoresist pattern 710 may be formed on the hard mask layer (not shown).

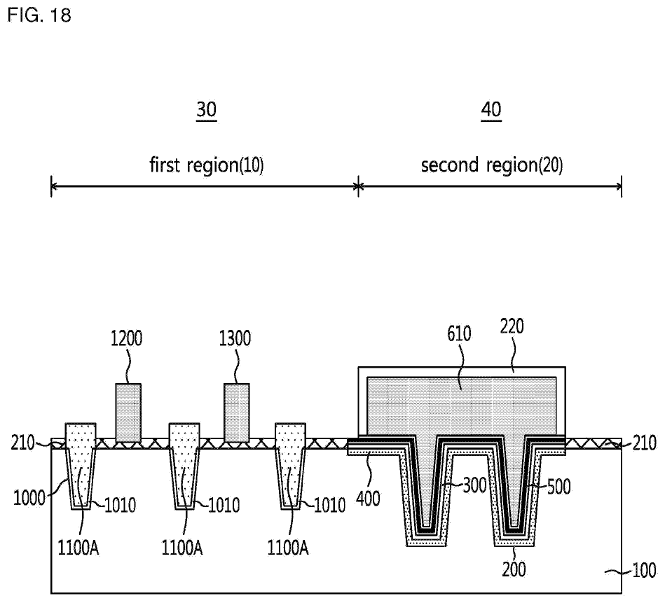

FIG. 18 illustrates the formation of a gate electrode by patterning a second conductive layer.

A reactive ion etching (RIE) process is performed on the second conductive layer 800 to form logic gate electrodes 1200 and 1300 in the first region 10 with the fourth photoresist pattern 710. As used herein, the reactive ion etching (RIE) process is a dry etching process. The logic gate electrodes 1200 and 1300 are made of the same material as the upper electrode 610.

After the RIE process, the fourth photoresist pattern 710 and the hard mask layer may be removed, and the second gate insulating layer 220 on the upper electrode 610 may be exposed. Thereby, the second gate insulating layer 220 may protect the upper electrode 610 during the RIE process.

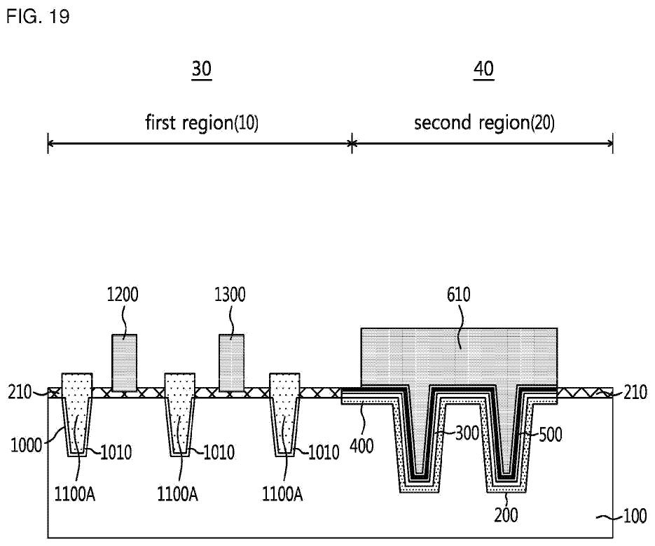

FIG. 19 illustrates the removal of the second gate insulating layer on the upper electrode.

Referring to FIG. 19, a wet etching process may be performed to remove the second gate insulating layer 220 and then expose the upper electrode 610 in the second region 20.

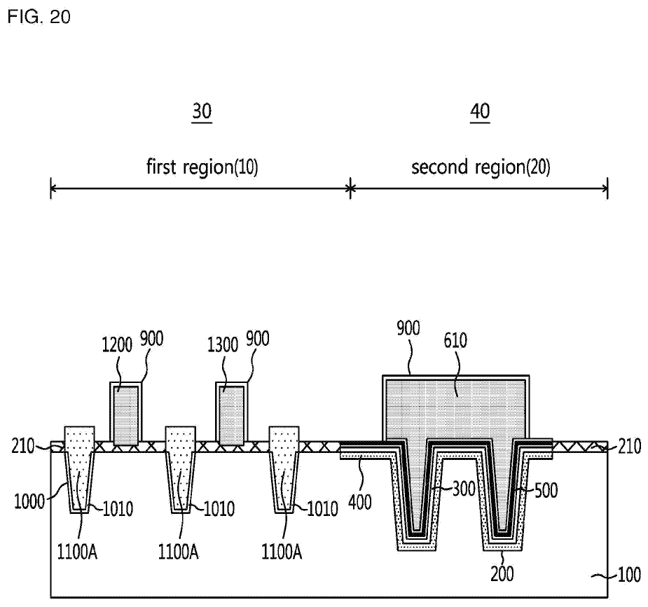

FIG. 20 illustrates the formation of a thermal oxide layer on the logic gate electrode and the upper electrode.

Referring to FIG. 20, a thermal oxidation process is performed to form a thermal oxide layer 900 on each exposed surface of the logic gate electrodes 1200 and 1300 and the upper electrode 610. The thermal oxide layer 900 may cure damages to the logic gate electrodes 1200 and 1300 caused by the previous dry etching process.

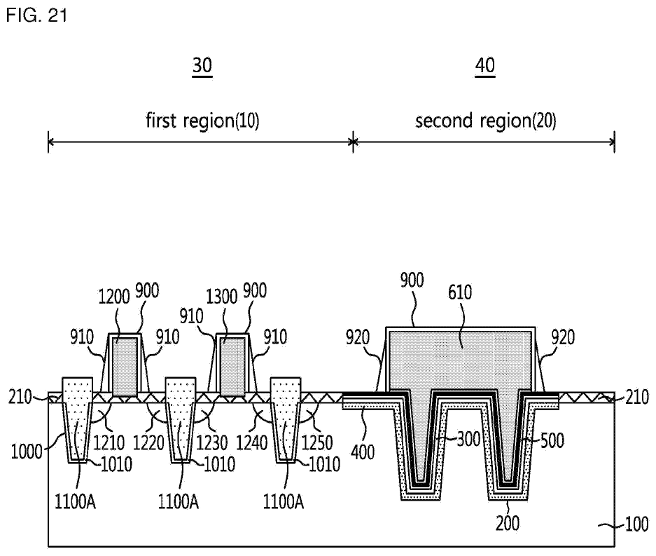

FIG. 21 illustrates forming a gate spacer and an upper electrode spacer on sidewalls of the logic gate electrode and the upper electrode, and forming a source region and a drain region around the logic gate electrode.

Referring to FIG. 21, a logic gate spacer 910 and an upper electrode spacer 920 may be formed on sidewalls of the logic gate electrodes 1200 and 1300 and the upper electrode 610, respectively.

N+ source/drain regions 1210 and 1220 are formed adjacent to the NMOS gate 1200. P+ source/drain regions 1230 and 1240 are formed adjacent to the PMOS gate 1300. A P+ pickup region 1250 may be formed on the substrate 100 between the logic devices 30 and the trench capacitor 40.

According to such a process, the process of forming the logic device 30 is performed after forming the trench capacitor 40, thereby minimizing the effect of high temperature annealing on the logic device 30. In addition, this process enables the trench capacitor 40 and the logic device 30 to be formed on a single chip, thereby reducing device manufacturing costs compared to a process in which chips with each region are fabricated separately and then designed on a PCB substrate.

According to the present disclosure, a process in which a trench capacitor 40 is formed is performed first, and a process in which various devices for processing digital or analog signals are formed in logic devices 30 is performed later. Thus, semiconductor devices can be produced with the effect of minimizing the influence on the components used for signal processing.

According to the present disclosure, a trench capacitor and a circuit region for signal processing may be fabricated in a one-chip form, resulting in cost savings in the production of semiconductor devices.

Although the description has been made with reference to the illustrated embodiments of the present invention as described above, these are merely examples, and those skilled in the art to which the present invention belongs will appreciate that other embodiments, which are variations, modifications and equivalents are possible. Therefore, the true technical scope of protection of the present invention should be determined by the technical spirit of the appended claims.

What is claimed is:

1. A method of manufacturing a semiconductor device, the method comprising:
forming a deep trench in a substrate;
performing an ion implantation process to form a lower electrode along with the deep trench;
forming a dielectric layer on the lower electrode;
filling a first conductive layer into the deep trench;
performing a planarization process on the first conductive layer to form an upper electrode in the deep trench such that a trench capacitor is formed in the deep trench;
forming a shallow trench adjacent to the deep trench;
forming a logic gate insulating layer adjacent to the shallow trench;
forming a logic gate electrode on the logic gate insulating layer; and
forming a source region and a drain region adjacent to the logic gate electrode,
wherein the logic gate electrode is made of a same material as the upper electrode.

2. The method of claim 1, wherein the forming of the deep trench in the substrate comprises:
forming a deep trench hard mask pattern on the substrate; and
performing an etching process on the substrate to form the deep trench with the deep trench hard mask pattern.

3. The method of claim 1, wherein the forming of the dielectric layer on the lower electrode comprises:
forming a first dielectric layer in the deep trench; and
forming a second dielectric layer on the first dielectric layer, and
wherein the first dielectric layer comprises a first material that is different from a second material of the second dielectric layer.

4. The method of claim 1, further comprising:
forming thermal oxide layers on the upper electrode and the logic gate electrode; and
forming spacers on sidewalls of the upper electrode and the logic gate electrode.

5. The method of claim 1, further comprising:
performing a high temperature annealing process on the planarized first conductive layer or the upper electrode.

6. The method of claim 1, wherein the performing of the planarization process on the first conductive layer to form the upper electrode in the deep trench comprises:
performing a first chemical mechanical planarization (CMP) process on the first conductive layer to form a planarized first conductive layer; and
performing a second CMP process to remove the dielectric layer exposed by the first CMP.

7. The method of claim 1, further comprising:
performing a gap-fill process on the shallow trench with a thick insulating layer; and
performing a third CMP process on the thick insulating layer.

8. A method of manufacturing a semiconductor device, the method comprising:
providing a first region and a second region in a semiconductor substrate;
forming a deep trench hard mask pattern in the second region;
forming a deep trench in the second region with the deep trench hard mask pattern;
forming a lower electrode along with the deep trench;
forming a dielectric layer on the lower electrode;
performing a gap-filling process in the deep trench with a first conductive layer;
performing a first planarization process on the first conductive layer to form an upper electrode in the deep trench;
forming a shallow trench hard mask pattern in the first region;
forming a shallow trench in the first region with the shallow trench hard mask pattern;
filling the shallow trench with a thick insulating layer;
performing a second planarization process on the thick insulating layer to form a planarized thick insulating layer in the shallow trench;
forming a logic gate insulating layer adjacent to the shallow trench;
forming a second conductive layer on the logic gate insulating layer;
performing a patterning process on the second conductive layer to form a logic gate electrode in the first region; and
forming a source region and a drain region around the logic gate electrode, wherein the first conductive layer is a same material as the second conductive layer.

9. The method of claim 8, wherein the forming of the lower electrode comprises performing an ion implantation process along with the deep trench.

10. The method of claim 8, further comprising:
forming a thermal oxide layer on each surface of the logic gate electrode and the upper electrode.

11. The method of claim 8, wherein the performing of the first planarization process on the first conductive layer to form the upper electrode in the deep trench comprises:
performing a first chemical mechanical planarization (CMP) process on the first conductive layer to form a planarized first conductive layer; and performing a second CMP process to remove the dielectric layer exposed by the first CMP.

12. The method of claim 8, further comprising:
performing a high temperature annealing process on the planarized first conductive layer or the upper electrode.

13. A method of manufacturing a semiconductor device, the method comprising:
providing a first region and a second region in a substrate;
forming a deep trench in the second region;
forming a lower electrode along with the deep trench;
forming a dielectric layer on the lower electrode;
filling a first conductive layer into the deep trench;
performing a planarization process on the first conductive layer to form an upper electrode in the deep trench such that a trench capacitor is formed in the deep trench;
forming a shallow trench adjacent to the deep trench;
filling the shallow trench with a thick insulating layer to form a shallow trench isolation;
forming a first gate insulating layer on the substrate in the first region, and forming a second gate insulating layer on the upper electrode in the second region;
forming a second conductive layer on the first and second gate insulating layers;
performing a patterning process on the second conductive layer to form a logic gate electrode in the first region; and
forming source and drain regions adjacent to the logic gate electrode.

14. The method of claim 13, wherein the dielectric layer comprises a first insulating layer, a second insulating layer, and a third insulating layer, and
wherein the first and third insulating layers are formed of a same material, and the second insulating layer is formed of a material different from that of the first and third insulating layers.

15. The method of claim 14, wherein the first and third insulating layers comprise Al₂O₂ or SiO₂, and the second insulating layer comprises HfO₂, SiN or SiON.
